(19) United States
(12) Patent Application Publication
(10) Pub. No.: US 2010/0238054 A1
(43) Pub. Date: Sep. 23, 2010

(54) KEYBOARD DEVICE AND METHOD FOR IDENTIFYING DIFFERENT KEY FUNCTIONS ON THE KEYBOARD DEVICE

(75) Inventor: Pei-Ming Chang, Taipei (TW)

Correspondence Address: KIRTON AND MCCONKIE, 60 EAST SOUTH TEMPLE,, SUITE 1800, SALT LAKE CITY, UT, 84111, US

(73) Assignee: PRIMAX ELECTRONICS LTD., Taipei (TW)

(21) Appl. No.: 12/426,836

(22) Filed: Apr. 20, 2009

(30) Foreign Application Priority Data
Mar. 20, 2009 (TW) 098109042

(51) Int. Cl. H03M 11/00

(52) U.S. Cl. 341/22

(57) ABSTRACT

A keyboard device and a key function identification method are provided. The keyboard device includes a micro-controller, a wire circuit and multiple keys. A key code table has been previously stored in the micro-controller. The multiple keys have different key identification parts. When the key identification parts are electrically connected the wire circuit, different key codes are generated. According to different key codes and the key code table, different key signals are generated.

### FIELD OF THE INVENTION

The present invention relates to a keyboard device, and more particularly to a keyboard device capable of identifying different keys functions according to key codes.

### BACKGROUND OF THE INVENTION

With rapid development of electronic and information industries, computers and the peripheral device thereof become essential parts in our daily lives. In addition to the working purposes, computers can be employed as amusement tools. In the computer systems, input devices play important roles for communicating the computer and the user. The common input devices of the computer systems are for example mice, keyboards or a trackballs. The subject of the present invention is directed to a keyboard device for inputting instructions to a computer by pressing multiple keys.

FIG. 1 is a schematic view illustrating the outward appearance of a conventional keyboard device. The surface of the keyboard device 1 includes a plurality of keys. These keys include ordinary keys 10, numeric keys 11 and function keys 12. When one or more keys are depressed, the computer executes a corresponding function. For example, when the ordinary keys 10 are depressed, corresponding English letters or symbols are inputted into the computer system. The function keys 12 (F1˜F12) can be programmed to cause the application program to perform certain functions.

FIG. 2 is a schematic circuit diagram illustrating the internal circuitry of the conventional keyboard device. The keyboard device 1 includes a microprocessor 13 and a keyboard scanning matrix 14. The microprocessor 13 is connected with multiple input/output (I/O) ports through multiple pins. The other parts of the microprocessor 13 are known in the art, and are not redundantly described herein. The keyboard scanning matrix 14 includes multiple I/O ports (X0˜X7 and Y0—YG). These I/O ports crisscross to define a plurality of keys on the surface of the keyboard device 1. Since the keyboard scanning matrix 14 is an 8×16 matrix, there are a total of 128 intersection points correlating to 128 keys on the surface of the keyboard device 1. That is, if there are 128 keys on the surface of the keyboard device 1, the internal circuit of the keyboard device 1 should have at least 24 I/O ports.

With the maturity of computing technologies, the keyboard devices with basic functions fail to meet the users' requirements. The keyboard manufacturers make efforts in designing novel keyboard devices with increased number of I/O ports and increased number of keys. Since the space within the keyboard device 1 is limited, the increased number of keys is still insufficient to meet the users' requirements.

Nowadays, computer games and online games are gaining popularity. For playing these games, the user needs to skillfully operate the keyboard device 1. If the common keys of a keyboard device are located at the sites that the users can quickly move their fingers thereon, the convenience of operating the keyboard device is enhanced. Since the internal circuitry of the keyboard device is fixed, the key positions on the keyboard device fail to be moved as required. Before the users are familiar with the key positions on the keyboard device, the users usually feel that the keyboard device is not easy-to-use and readily erroneously operated.

### SUMMARY OF THE INVENTION

It is an object of the present invention to provide a keyboard device with enhanced key expandability.

Another object of the present invention provides a keyboard device having adjustable key positions.

In accordance with an aspect of the present invention, there is provided a keyboard device communicated with a computer. The keyboard device includes a micro-controller, a wire circuit and multiple keys. The micro-controller is disposed on a circuit board. A key code table has been previously stored in the micro-controller. The wire circuit is connected to the micro-controller. The multiple keys are arranged over the wire circuit. Each key includes a keycap and a key identification part. The keycap is exposed outside of the keyboard device to be depressed. The key identification part is disposed under the keycap and in the vicinity of the wire circuit and includes at least one long protrusion and at least one short protrusion. When one of the multiple keys is depressed, the key identification part of the depressed key is contacted with the wire circuit and a key code is generated, and the micro-controller executes a function of the depressed key according to the key code and the key code table. The key code of each key is determined according to the number of the long protrusion and the number of the short protrusion included in the key identification part.

In an embodiment, the key code is encoded as a binary key code, the binary key code is converted into a hexadecimal key code by the micro-controller, and a function of the depressed key is executed according to the hexadecimal key code and the key code table.

In an embodiment, the key code table is a human input device usage table.

In an embodiment, the long protrusion of the key identification part is longer than the short protrusion. When the keycap is depressed, the long protrusion is contacted with the wire circuit such that a high logic-level signal having a logic value 1 is issued, but the short protrusion is separated from the wire circuit such that a low logic-level signal having a logic value 0 is issued.

In an embodiment, the key code includes high logic-level signals and low logic-level signal.

In an embodiment, the micro-controller issues a key signal to the computer according to the key code and the key code table, and the computer executes a function of the depressed key according to the key signal.

In an embodiment, the micro-controller further comprises multiple input/output ports respectively connected with multiple wires of the wire circuit.

In an embodiment, both terminals of the key identification part are connected to ground.

In an embodiment, both terminals of the key identification part are connected to a high logic-level voltage.

In an embodiment, the keyboard device further includes a signal power circuit, which is connected to the micro-controller for providing electricity and transmitting signals to the micro-controller.

In an embodiment, the keyboard device further includes a capacitor regulator, which is connected to the micro-controller for providing a reference voltage.

In an embodiment, the keyboard device further includes an oscillating circuit, which is connected to the micro-controller for driving the micro-controller.

In an embodiment, the keyboard device further includes an indicator lamp circuit, which is connected to the micro-controller for providing several lighting prompts to indicate different operating statuses of the keyboard device.

In an embodiment, the keyboard device further includes a filtering circuit, which is connected to the micro-controller for filtering off noise.

In accordance with another aspect of the present invention, there is provided a key function identification method for use in a keyboard device. The keyboard device includes multiple keys and a key code table. The key function identification method includes steps of generating a binary key code when one of the multiple keys is depressed, and identifying a function of the depressed key according to the binary key code and aid key code table.

In an embodiment, the key code table is a human input device usage table.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic view illustrating the outward appearance of a conventional keyboard device;

FIG. 2 is a schematic circuit diagram illustrating the internal circuitry of the conventional keyboard device;

FIG. 3 is a schematic circuit diagram illustrating the internal circuitry of a keyboard device according to an embodiment of the present invention;

FIG. 4 is a schematic view illustrating the relative locations between a first key and multiple wires of the keyboard device according to an embodiment of the present invention; and

FIG. 5 is a schematic view illustrating the relative locations between a second key and multiple wires of the keyboard device according to an embodiment of the present invention.

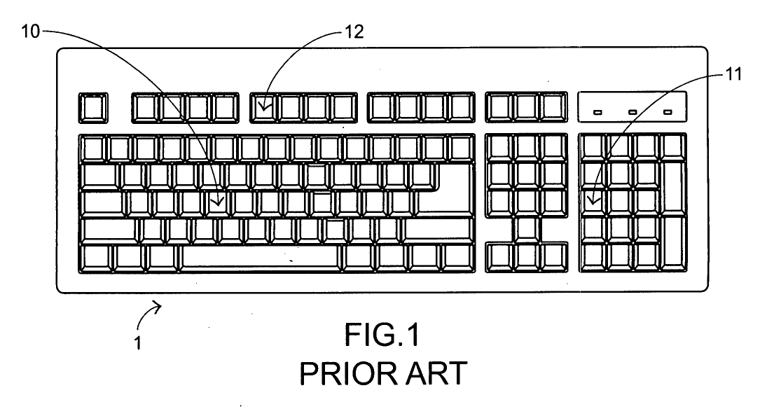

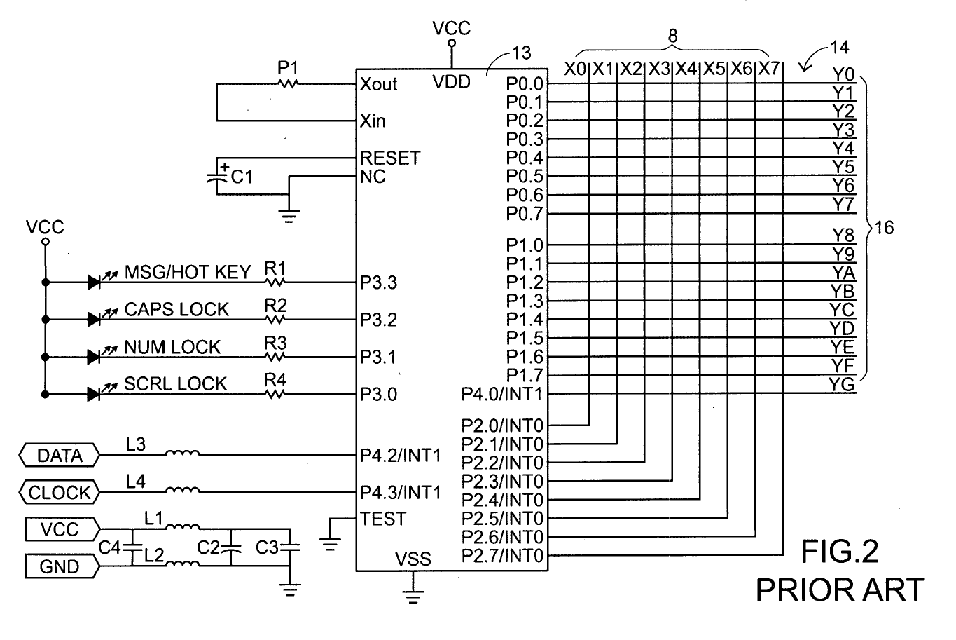

### DETAILED DESCRIPTION OF THE PREFERRED EMBODIMENT

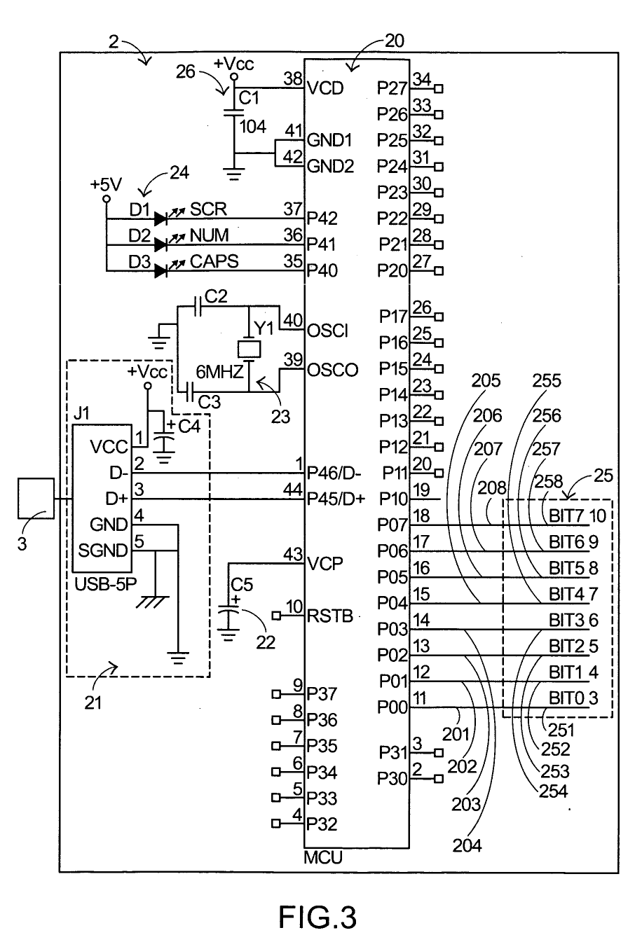

FIG. 3 is a schematic circuit diagram illustrating the internal circuitry of a keyboard device according to an embodiment of the present invention. The keyboard device 2 is communicated with a computer 3. The keyboard device 2 comprises a micro-controller 20, a signal power circuit 21, a capacitor regulator 22, an oscillating circuit 23, an indicator lamp circuit 24, a wire circuit 25, a filtering circuit 26 and a plurality of keys (not shown).

The micro-controller 20 is disposed on a circuit board (not shown). The micro-controller 20 includes eight I/O ports 201˜208. The signal power circuit 21 is connected to the micro-controller 20 for providing electricity and signals to the micro-controller 20. The capacitor regulator 22 is also connected to the micro-controller 20 for providing a reference voltage. The oscillating circuit 23 is connected to the micro-controller 20 for driving the micro-controller 20. The indicator lamp circuit 24 is connected to the micro-controller 20 for providing several lighting prompts to indicate different operating statuses of the keyboard device 2. The filtering circuit 26 is connected to the micro-controller 20 for filtering off noise. The wire circuit 25 includes a first wire 251, a second wire 252, a third wire 253, a fourth wire 254, a fifth wire 255, a sixth wire 256, a seventh wire 257 and an eighth wire 258. The first wire 251 is connected with the micro-controller 20 through the first I/O port 201. The second wire 252 is connected with the micro-controller 20 through the second I/O port 202. Similarly, the wires 253˜258 are connected with the micro-controller 20 through the I/O ports 203˜208, respectively.

The keyboard device 2 has a plurality of keys. When the keys are depressed, corresponding functions are executed. The keys are disposed over the wire circuit 25. When a key is depressed, the key is electrically connected with a corresponding wire and thus a corresponding key signal is transmitted to the computer 3 through the wire. For identifying which key is depressed to accurately execute the function of the depressed key. In accordance with a feature of the present invention, a key code table has been previously stored in the micro-controller 20 of the keyboard device 2. The key code table concerns the relationships between the keys and corresponding codes. When a key is depressed, the micro-controller 20 will realize the code of the depressed key by the key code table. According to the code, the micro-controller 20 issues a corresponding key signal to the computer 3, so that the computer 3 executes a corresponding function. In an embodiment of the present invention, the key code table is illustrated with the following human input device (HID) usage table.

| Key | Code |
|---|---|
| a A | 04 |
| b B | 05 |
| c C | 06 |
| d D | 07 |
| e E | 08 |
| f F | 09 |
| g G | 0A |
| h H | 0B |
| i I | 0C |
| j J | 0D |
| k K | 0E |
| l L | 0F |
| m M | 10 |
| n N | 11 |
| o O | 12 |
| p P | 13 |
| q Q | 14 |
| r R | 15 |
| s S | 16 |
| t T | 17 |
| u U | 18 |
| v V | 19 |
| w W | 1A |
| x X | 1B |
| y Y | 1C |
| z Z | 1D |
| 1 ! | 1E |
| 2 @ | 1F |
| 3 # | 20 |
| 4 $ | 21 |
| 5 % | 22 |
| 6 \hat{ } | 23 |
| 7 & | 24 |
| 8 * | 25 |
| 9 ( | 26 |
| 0 ) | 27 |
| Return | 28 |
| Escape | 29 |
| Backspace | 2A |
| Tab | 2B |
| Space | 2C |
| - _{—} | 2D |
| = + | 2E |
| [ { | 2F |
| ] } | 30 |
| \ \| | 31 |
| Europe 1 | 32 |
| ; : | 33 |
| ' “ | 34 |
| \grave{ } ~ | 35 |
| , < | 36 |
| . > | 37 |
| / ? | 38 |
| Caps Lock | 39 |
| F1 | 3A |
| F2 | 3B |
| F3 | 3C |
| F4 | 3D |
| F5 | 3E |
| F6 | 3F |
| F7 | 40 |
| F8 | 41 |
| F9 | 42 |
| F10 | 43 |
| F11 | 44 |
| F12 | 45 |
| Print Screen | 46 |
| Scroll Lock | 47 |
| Break | 48 |
| (Ctrl-Pause) | |
| Pause | 48 |
| Insert | 49 |
| Home | 4A |
| Page Up | 4B |
| Delete | 4C |
| End | 4D |
| Page Down | 4E |
| Right Arrow | 4F |
| Left Arrow | 50 |
| Down | 51 |
| Arrow | |
| Up Arrow | 52 |
| Num Lock | 53 |
| Keypad / | 54 |
| Keypad * | 55 |
| Keypad − | 56 |
| Keypad + | 57 |
| Keypad | 58 |
| Enter | |
| Keypad 1 | 59 |
| End | |
| Keypad 2 | 5A |
| Down | |
| Keypad 3 | 5B |
| PageDn | |
| Keypad 4 | 5C |
| Left | |
| Keypad 5 | 5D |
| Keypad 6 | 5E |
| Right | |
| Keypad 7 | 5F |
| Home | |
| Keypad 8 | 60 |
| Up | |
| Keypad 9 | 61 |
| PageUp | |
| Keypad 0 | 62 |
| Insert | |
| Keypad . | 63 |
| Delete | |
| Europe 2 | 64 |
| (Note 2) | |
| App | 65 |
| Keyboard | 66 |
| Power | |
| Keypad = | 67 |
| F13 | 68 |
| F14 | 69 |
| F15 | 6A |
| F16 | 6B |
| F17 | 6C |
| F18 | 6D |
| F19 | 6E |
| F20 | 6F |
| F21 | 70 |
| F22 | 71 |
| F23 | 72 |
| F24 | 73 |
| Execute | 74 |
| Help | 75 |
| Menu | 76 |
| Select | 77 |
| Stop | 78 |
| Again | 79 |
| Undo | 7A |
| Cut | 7B |
| Copy | 7C |
| Paste | 7D |
| Find | 7E |
| Mute | 7F |
| Volume | 80 |
| Up | |
| Volume | 81 |
| Dn | |
| Locking | 82 |
| Caps Lock | |
| Locking | 83 |
| Num Lock | |
| Locking | 84 |
| Scroll | |
| Lock | |
| (Brazilian | 85 |
| Keypad .) | |
| Equal | 86 |
| Sign | |
| Int'l 1 | 87 |
| Intl'2 | 88 |
| Int'l 3 | 89 |
| Int'l 4 | 8A |
| Int'l 5 | 8B |
| Int'l 6 | 8C |
| Int'l 7 | 8D |
| Int'l 8 | 8E |
| Int'l 9 | 8F |
| Lang 1 | 90 |
| Lang 2 | 91 |
| Lang 3 | 92 |
| Lang 4 | 93 |
| Lang 5 | 94 |
| Lang 6 | 95 |
| Lang 7 | 96 |
| Lang 8 | 97 |
| Lang 9 | 98 |
| Alternate | 99 |
| Erase | |
| SysReq/ | 9A |
| Attention | |
| Cancel | 9B |
| Clear | 9C |
| Prior | 9D |
| Return | 9E |
| Separator | 9F |
| Out | A0 |
| Oper | A1 |
| Clear/Again | A2 |
| CrSel/Props | A3 |
| ExSel | A4 |
| Left Control | E0 |
| Left Shift | E1 |
| Left Alt | E2 |
| Left GUI | E3 |
| Right | E4 |
| Control | |
| Right Shift | E5 |
| Right Alt | E6 |
| Right GUI | E7 |

The above HID usage table is written according a hexadecimal system. In contrast to the decimal system, the hexadecimal system uses sixteen distinct symbols. The symbols 0˜9 represent the values zero to nine. The symbols A, B, C, D, E and F represent the values ten, eleven, twelve, thirteen, fourteen and fifteen, respectively. For example, the key “y” has a key code “1C”. The symbol 1C in the hexadecimal system represents the value 28 in the decimal system. Whereas, the symbol 1C in the hexadecimal system represents the value 00011100 in the binary system.

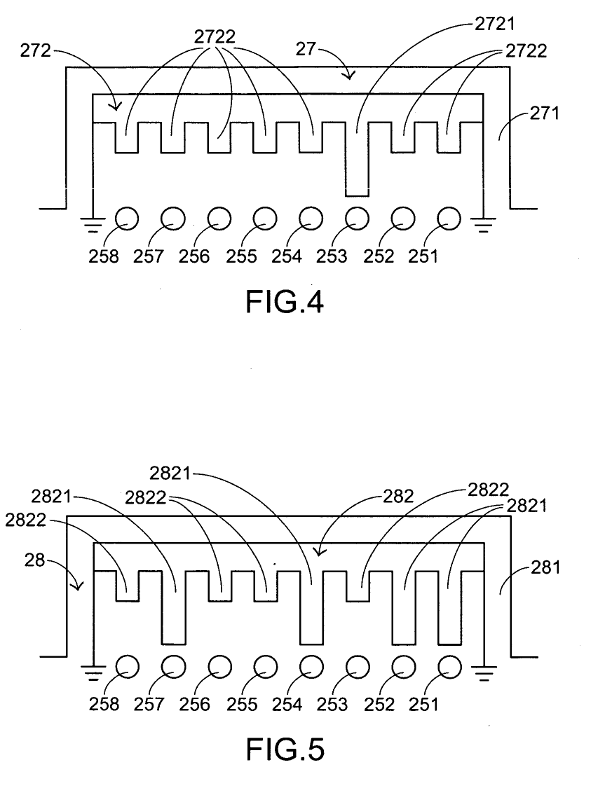

FIG. 4 is a schematic view illustrating the relative locations between a first key and multiple wires of the keyboard device according to an embodiment of the present invention. As shown in FIG. 4, the first key 27 includes a first keycap 271 and a first key identification part 272. The first keycap 271 is exposed outside of the keyboard device 2 such that the first keycap 271 can be depressed. The first key identification part 272 is disposed under the first keycap 271 and in the vicinity of the wire circuit 25. According to the settings of the micro-controller 20, the both terminals of the first key identification part 272 are selectively connected to ground or a high logic-level voltage (VCC). In this embodiment, both terminals of the first key identification part 272 are connected to ground.

As shown in FIG. 4, the first key identification part 272 includes a long protrusion 2721 and seven short protrusions 2722. The long protrusion 2721 and the short protrusions 2722 correspond to respective wires of the wire circuit 25. In this embodiment, the long protrusion 2721 is arranged over the third wire 253. When the first keycap 271 is depressed, the first key identification part 272 is moved downwardly to be contacted with the wire circuit 25 and thus the wire circuit 25 issues a first key code to the micro-controller 20. In particular, when the first keycap 271 is depressed, the long protrusion 2721 of the first key identification part 272 is contacted with the third wire 253, so that a high logic-level signal (e.g. logic value=1) is issued to the micro-controller 20. Since the wires 251, 252, 254, 255, 256, 257 and 258 under the seven short protrusions 2722 are still separated from the short protrusions 2722, low logic-level signals (e.g. logic value=0) are issued from these wires to the micro-controller 20. Under this circumstance, the first key code represented in the binary system is 00000100.

By the micro-controller 20, the value 00000100 is converted into a value 04 in the hexadecimal system. According to the key code table (i.e. the HID usage table), the first key code 04 corresponds to the key A. When the first key 27 is depressed, a first key signal transmitted from the micro-controller 20 to the computer 3 and thus the computer 3 executes the function associated with the key A.

In accordance with a feature of the present invention, the key identification parts of all keys of the keyboard device 2 are different, so that diverse functions could be provided. The key codes generated from the keyboard device 2 are determined according to the numbers and positions of the long protrusion and short protrusion included in the keyboard device 2.

FIG. 5 is a schematic view illustrating the relative locations between a second key and multiple wires of the keyboard device according to an embodiment of the present invention. The configurations of the second key 28 are similar to those of the first key 27. The second key 28 includes a second keycap 281 and a second key identification part 282. Both terminals of the second key identification part 282 are connected to ground. Whereas, the second key identification part 282 has four long protrusions 2821 and four short protrusions 2822. In this embodiment, these four long protrusions 2821 are respectively arranged over the first wire 251, the second wire 252, the fourth wire 254 and the seventh wire 257. When the second keycap 281 is depressed, the second key identification part 282 is moved downwardly to be contacted with the first wire 251, the second wire 252, the fourth wire 254 and the seventh wire 257. As such, the wire circuit 25 issues a second key code to the micro-controller 20. Under this circumstance, the second key code represented in the binary system is 01001011. By the micro-controller 20, the value 01001011 is converted into a value 4B in the hexadecimal system. According to the key code table, the second key code 4B corresponds to the key PageUp. When the second key 28 is depressed, a second key signal transmitted from the micro-controller 20 to the computer 3 and thus the computer 3 executes the function associated with the key PageUp.

In the above embodiments, the key identification parts of all keys of the keyboard device 2 are different. In cooperation with the eight wires of the wire circuit 25, the keyboard device 2 can provide 256 keys (2⁸=256).

From the above description, the keyboard device 2 of the present invention uses eight I/O ports 201˜208 and multiple keys with different key identification parts in replace of the keyboard scanning matrix of the conventional keyboard device. The extra I/O ports of the micro-controller 20 could be connected with other electronic components in order to expand the functions of the keyboard device 2. On the other hand, only few additional keys may be mounted on the conventional keyboard device. According to the present invention, the wire circuits 25 under all keys of the keyboard device 2 are identical, and the differences between all keys are realized according to the distinguishable key identification parts. As a consequence, the positions of keys can be altered according to the practical requirements. For mounting one or more keys on specified positions of the keyboard device, the user may detach the keys from the keyboard device and then mount these keys on desired positions of the keyboard device. Under this circumstance, the possibility of erroneously operating the keyboard device is minimized.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A keyboard device communicated with a computer, said keyboard device comprising:
a micro-controller disposed on a circuit board, wherein a key code table has been previously stored in said micro-controller;
a wire circuit connected to said micro-controller; and
multiple keys arranged over said wire circuit, and each key comprising a keycap and a key identification part, wherein said keycap is exposed outside of said keyboard device to be depressed, and said key identification part is disposed under said keycap and in the vicinity of said wire circuit and includes at least one long protrusion and at least one short protrusion,
wherein when one of said multiple keys is depressed, said key identification part of said depressed key is contacted with said wire circuit and a key code is generated, and said micro-controller executes a function of said depressed key according to said key code and said key code table, wherein said key code of each key is determined according to the number of said long protrusion and the number of said short protrusion included in said key identification part.

2. The keyboard device according to claim 1 wherein said key code is encoded as a binary key code, said binary key code is converted into a hexadecimal key code by said micro-controller, and a function of said depressed key is executed according to said hexadecimal key code and said key code table.

3. The keyboard device according to claim 1 wherein said key code table is a human input device usage table.

4. The keyboard device according to claim 1 wherein said long protrusion of said key identification part is longer than said short protrusion, wherein when said keycap is depressed, said long protrusion is contacted with said wire circuit such that a high logic-level signal having a logic value 1 is issued, but said short protrusion is separated from said wire circuit such that a low logic-level signal having a logic value 0 is issued.

5. The keyboard device according to claim 4 wherein said key code includes high logic-level signals and low logic-level signal.

6. The keyboard device according to claim 1 wherein said micro-controller issues a key signal to said computer according to said key code and said key code table, and said computer executes a function of said depressed key according to said key signal.

7. The keyboard device according to claim 1 wherein said micro-controller further comprises multiple input/output ports respectively connected with multiple wires of said wire circuit.

8. The keyboard device according to claim 1 wherein both terminals of said key identification part are connected to ground.

9. The keyboard device according to claim 1 wherein both terminals of said key identification part are connected to a high logic-level voltage.

10. The keyboard device according to claim 1 further comprising a signal power circuit, which is connected to said micro-controller for providing electricity and transmitting signals to the micro-controller.

11. The keyboard device according to claim 1 further comprising a capacitor regulator, which is connected to said micro-controller for providing a reference voltage.

12. The keyboard device according to claim 1 further comprising an oscillating circuit, which is connected to said micro-controller for driving said micro-controller.

13. The keyboard device according to claim 1 further comprising an indicator lamp circuit, which is connected to said micro-controller for providing several lighting prompts to indicate different operating statuses of said keyboard device.

14. The keyboard device according to claim 1 further comprising a filtering circuit, which is connected to said micro-controller for filtering off noise.

15. A key function identification method for use in a keyboard device, said keyboard device comprising multiple keys and a key code table, said key function identification method comprising steps of:
generating a binary key code when one of said multiple keys is depressed; and
identifying a function of said depressed key according to said binary key code and aid key code table.

16. The key function identification method according to claim 15 wherein said key code table is a human input device usage table.
